(19) United States
(12) Patent Application Publication
(10) Pub. No.: US 2026/0371745 A1
(43) Pub. Date: Nov. 19, 2026

(54) SILICON-ON-INSULATOR (SOI) STRUCTURES FOR CHARGE DAMAGE PROTECTION

(71) Applicant: Taiwan Semiconductor Manufacturing Company, Ltd., Hsinchu (TW)

(72) Inventor: Hung-Te Lin, Hsinchu (TW)

(21) Appl. No.: 19/752,675

(22) Filed: Jul. 24, 2026

Related U.S. Application Data
(62) Division of application No. 18/452,556, filed on Aug. 20, 2023.

(51) Int. Cl. H10D 89/60; H10D 87/00; H10P 90/00; H10W 10/00; H10W 10/10; H10W 10/17

(52) U.S. Cl. CPC H10D 89/921; H10D 87/00; H10D 89/611; H10D 89/931; H10P 90/1906; H10P 90/1908; H10W 10/014; H10W 10/061; H10W 10/17; H10W 10/181

(57) ABSTRACT

Methods for fabricating a semiconductor structure with charge damage protection are provided. The method includes providing a bulk substrate and forming a uniquely shaped heavily doped layer within it, which features a horizontal bottom portion and a downward-extending circumferential side portion. An insulating layer is then formed on the heavily doped layer, followed by the formation of an active substrate. This active substrate is completely isolated by the nested insulating and heavily doped layers, and its top surface is coplanar with the bulk substrate. To safely dissipate unwanted charges, an antenna diode is formed in the bulk substrate proximate to the active substrate. Finally, a semiconductor device is formed in the active substrate and electrically interconnected to the antenna diode using a first discharging metal structure.

### CROSS-REFERENCES TO RELATED APPLICATIONS

The present application is a divisional application of U.S. Patent Application 18/452,556, filed Aug. 20, 2023, the entire disclosure of which is incorporated herein by reference.

### FIELD

Embodiments of the present disclosure relate generally to semiconductor structures, and more particularly to silicon-on-insulator (SOI) structures.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs, and for these advances to be realized, similar developments in IC processing and manufacturing are needed. In the mainstream course of IC evolution, functional density (i.e., the number of interconnected devices per chip area) has generally increased while geometry size (i.e., the smallest component that can be created using a fabrication process) has decreased. Therefore, it has been a constant need to develop ICs with lower power consumption, better performance, smaller chip areas, and lower costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram illustrating a top view of a layout of an exemplary semiconductor structure in accordance with some embodiments.

FIG. 1B is a schematic diagram illustrating a cross-sectional view of the exemplary semiconductor structure of FIG. 1A in accordance with some embodiments.

FIG. 2A is a schematic diagram illustrating a top view of a layout of another exemplary semiconductor structure in accordance with some embodiments.

FIG. 2B is a schematic diagram illustrating a cross-sectional view of the exemplary semiconductor structure of FIG. 2A in accordance with some embodiments.

FIG. 2C is a schematic diagram illustrating a top view of another layout of the exemplary semiconductor structure of FIG. 2A in accordance with some embodiments.

FIG. 2D is a schematic diagram illustrating a top view of a layout of another exemplary semiconductor structure in accordance with some embodiments.

FIG. 3 is a schematic diagram illustrating a top view of a layout of yet another exemplary semiconductor structure in accordance with some embodiments.

FIG. 4 is a flowchart diagram illustrating an exemplary method for fabricating a semiconductor structure in accordance with some embodiments.

FIG. 5 is a flowchart diagram illustrating an exemplary operation shown in FIG. 4 in accordance with some embodiments.

FIGS. 6A-6N are cross-sectional diagrams illustrating an exemplary semiconductor structure, at various stages, fabricated using the exemplary methods shown in FIGS. 4-5.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as "beneath," "below," "lower," "above," "upper" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) (also referred to and used interchangeably as "S/D regions") may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Metal-induced charge damage, also known as antenna effect, refers to the undesired phenomenon where charges and ions can become trapped in the semiconductor lattice or at interfaces in semiconductor devices, leading to the introduction of unwanted energy levels within the bandgap of the materials. These energy levels can capture and trap charge carriers (electrons or holes), affecting the semiconductor device's electrical characteristics, such as carrier mobility, threshold voltage, and overall device performance. This phenomenon becomes more significant as ICs shrink in size and semiconductor devices become smaller and more densely packed. Metal-induced charge damage can cause signal degradation, physical damages such as metal migration, void formation, or interfacial degradation, unwanted interference among adjacent metal lines, increased power consumption, and potential reliability issues in the IC.

As an example, in IC fabrication using Metal-Oxide-Semiconductor (MOS) technology, processes involving charged ions are typically employed, such as a plasma etching process and an ion implantation process. For example, during a plasma etching process used in forming gate polysilicon patterns or interconnect metal line patterns, electrostatic charges may accumulate on a floating gate poly electrode. The resulting voltage on the gate poly electrode may become so large that charges may flow into the gate oxide, become trapped in the gate oxide or flow through the gate oxide. These charges may significantly degrade the gate oxide strength and cause MOS device reliability failures. Each poly gate region collects an electrostatic charge proportional to its own area. A small gate oxide region connected to a large poly geometry or a large interconnect metal geometry through poly contacts can accumulate a disproportionate amount of charges (positive plasma ions in the case of a grounded or a negative biased wafer) and may suffer serious damage. The strength of the antenna effect is proportional to the ratio between the exposed conductor area and the gate oxide area.

Semiconductor-on-insulator (SOI) substrates have emerged as an alternative to bulk semiconductor substrates. An SOI substrate generally comprises a bulk substrate (handle substrate), an insulator layer overlying the bulk substrate, and an active substrate (device substrate) overlying the insulator layer. Among other things, an SOI substrate leads to reduced parasitic capacitance, reduced leakage current, reduced latch-up, and improved semiconductor device performance (e.g., lower power consumption and higher switching speed).

For conventional SOI-based ICs, in order to discharge unwanted charges and mitigate antenna effect during the fabrication process, an electrical path from the active substrate to the bulk substrate, through the insulator layer is formed. Since the insulator layer separates the active substrate from the bulk substrate in the entire horizontal plane, a hole has to be created through the insulator layer, and a conducting material (e.g., metal) has to be filled in the hole. The charge release performance is restricted and compromised because the area of contact structures fabricated in the SOI substrate is not large enough. Moreover, the lateral isolation in an SOI-based IC is based on oxide formed using chemical vapor deposition (CVD) techniques, and the quality of CVD oxide is not as good as the quality of thermal oxide. Furthermore, the SOI fabrication process is more complex and costly than bulk silicon fabrication process.

The present disclosure provides techniques to address the above-mentioned shortcomings in connection with SOI-based ICs for antenna effect protection. One insight of the present disclosure is related to a novel SOI structure. According to some embodiments, the SOI structure has a three-dimensional (3D) sandwich configuration and includes a heavily doped layer, an insulating layer disposed on and surrounded by the heavily doped layer, and a distinct and discrete active substrate disposed on and surrounded by the insulating layer. The insulating layer buried in the SOI structure does not extend in the entire horizontal plane but rather has a folded configuration that laterally surrounds the active substrate to physically and electrically isolate the active substrate from the bulk substrate. A first discharging metal structure is used to electrically connect the semiconductor devices formed in the active substrate and the bulk substrate, such that an electrical path is formed to allow unwanted charges generated and accumulated in the active substrate to be released or dissipated to the bulk substrate through the first discharging metal structure, dispensing the need to form a through-insulator hole for discharging and preventing damages to the SOI structure. Moreover, the insulating layer can be made from a thermal oxide formed by a thermal process and thus have higher quality than the traditional SOI structure having CVD oxide-based insulating layer.

Another insight of the present disclosure is related to an antenna effect prevention device (also referred to as an "antenna diode"). According to some embodiments, an antenna effect prevention device is formed and arranged to be close to the SOI substrate in position. The antenna effect prevention device may be an antenna diode merged in the bulk substrate. A second discharging metal structure is used to interconnect the antenna effect prevention device and the semiconductor devices formed in the active substrate of the SOI structure. The second discharging metal structure may provide an additional electrical path to facilitate or improve the release and dissipation of the unwanted charges generated in the active substrate. According to some embodiments, an antenna metal structure may be formed and electrically connected to the antenna effect protection device to provide electrical paths for the release of unwanted charges generated in the multi-layer interconnect (MLI) structure (hereinafter "MLI structure") during the back-end-of-line (BEOL) process.

### Example Semiconductor Structures and SOI Structures

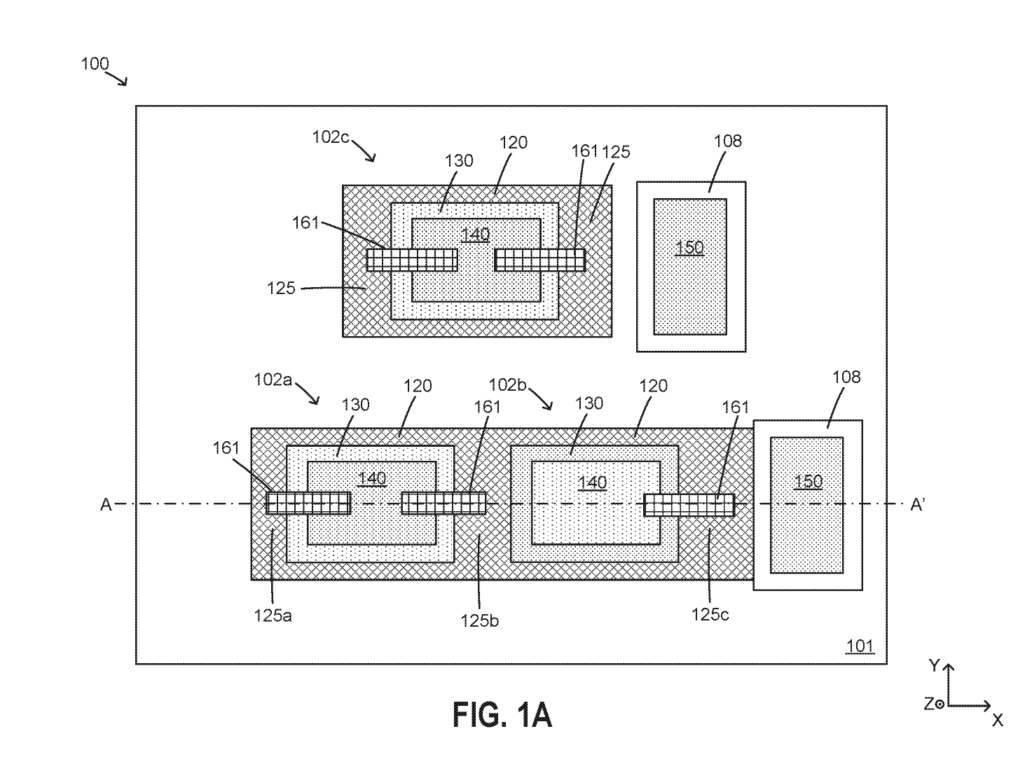

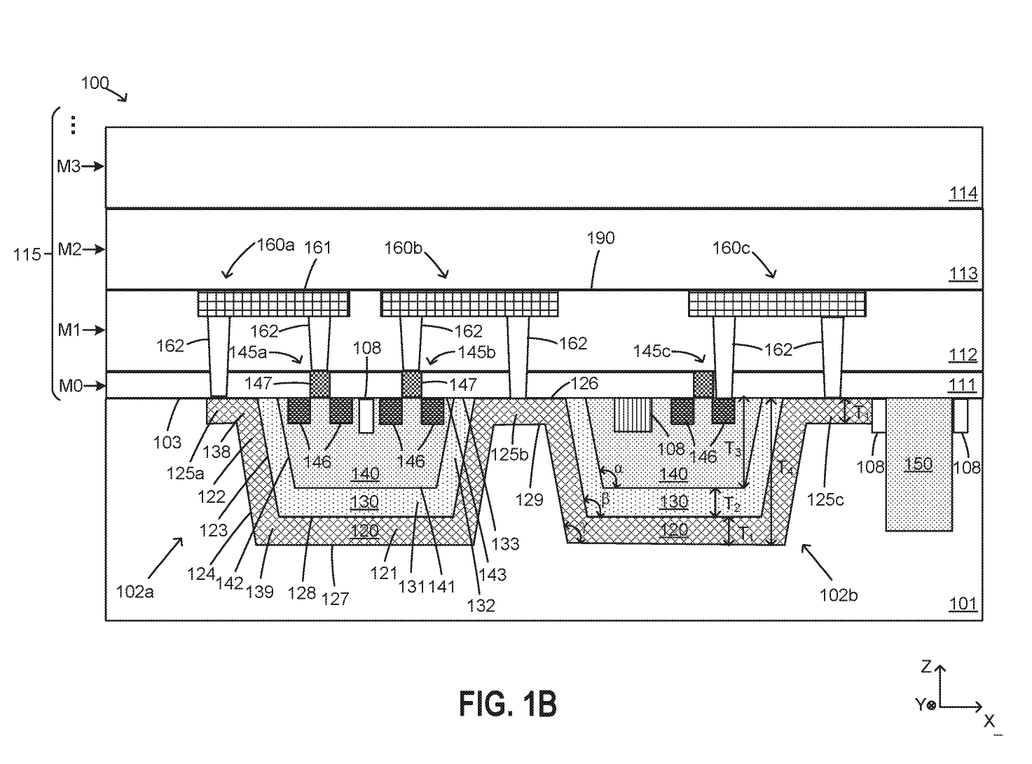

FIGS. 1A-1B illustrate an example semiconductor structure 100, in accordance with some embodiments. FIG. 1A is a schematic diagram illustrating a top view of a layout of the example semiconductor structure 100 from the surface 190 (i.e., the interface between M1 layer and M2 layer of the MLI structure 115). For purposes of simplicity, some components such as the dielectric layers 112 and 111 are not illustrated in FIG. 1A in order to depict other components of the semiconductor structure 100. FIG. 1B is a schematic diagram illustrating a cross-sectional view of the example semiconductor structure 100 at an imaginary line A-A' shown in FIG. 1A.

In the illustrated example, the semiconductor structure 100 includes, among other components, a bulk substrate 101, multiple SOI structures 102a, 102b, and 102c (collectively as the SOI structure 102), multiple IC devices (or semiconductor devices such as transistors) 145a, 145b, and 145c (collectively as IC device 145), an MLI structure 115, and multiple discharging metal structures 160a, 160b, and 160c (collectively as discharging metal structures 160). Additional components, such as multiple device regions 150, multiple shallow trench isolation (STI) structures 108, etc., may also be included in the semiconductor structure 100.

The bulk substrate 101 may be a semiconductor substrate such as a (single crystal) silicon substrate. In some embodiments, the bulk substrate 101 is a doped substrate having a dopant of a semiconductor type. For example, the bulk substrate 101 may be a p-type substrate or an n-type substrate. The bulk substrate 101 may have a first doping concentration (or dosage), for example, from 10¹³ to 10¹⁷ dopant atoms per square centimeter (cm²), from 10¹³ to 10¹⁶ dopant atoms per square centimeter (cm²), or from 10¹³ to 10¹⁵ dopant atoms per square centimeter (cm²). It should be noted that the other possible values of first doping concentration are also within the scope of the present disclosure. The bulk substrate 101 has a top surface 103.

Each of the SOI structures 102 is merged in the bulk substrate 101 and has a 3D sandwich configuration. In the example of FIG. 1B, the SOI structures 102 (e.g., the SOI structure 102a, 102b, and 102c) may each include, among other components, a corresponding portion of the bulk substrate 101 where the SOI structure 102 is built on, a heavily doped layer 120, an insulating layer 130 disposed on and surrounded by the heavily doped layer 120, and an active substrate 140 disposed on and surrounded by the insulating layer 130.

The heavily doped layer 120 may include a p-type dopant or an n-type dopant at a relatively high doping concentration. In some embodiments, the heavily doped layer 120 has the same type of dopant as the bulk substrate 101. In one example, both the heavily doped layer 120 the bulk substrate 101 are doped with a p-type dopant. In another example, both the heavily doped layer 120 the bulk substrate 101 are doped with an n-type dopant. In some embodiments, the heavily doped layer 120 has a higher or substantially higher doping concentration compared with the bulk substrate 101. In some embodiments, the doping concentration of the heavily doped layer 120 is higher than the doping concentration of the bulk substrate by at least 1 order (i.e., 10 times). In some embodiments, the heavily doped layer 120 has a second doping concentration, for example, from 10¹⁴ to 10²⁰ dopant atoms per square centimeter (cm²), or from 10¹⁵ to 10¹⁸ dopant atoms per square centimeter (cm²). It should be noted that the second doping concentration are also within the scope of the present disclosure.

The heavily doped layer 120 may provide at least the following benefits. The heavily doped layer 120 may provide a lower resistance path for the flow of electric current in the charge release process. The high doping concentration in the heavily doped layer may facilitate the formation of low-resistance contacts with other components in the semiconductor structure 100 to improve overall device performance. The heavily doped layer 120 may also provide another layer of barrier/isolation/protection in addition to the insulating layer 130, preventing unwanted leakage currents and improving isolation of the IC devices 145 formed within the SOI structure 102.

The heavily doped layer 120 includes a bottom portion 121 and a side portion 122. The bottom portion 121 is below the side portion 122 and extends in the horizontal plane (i.e., the X-Y plane). The bottom portion 121 vertically extends from a top surface 128 to a bottom surface 127. The side portion 122 circumferentially extends from a proximal sidewall 123 (i.e., proximal to the active substrate 140) to a distal sidewall 124 (i.e., distal to the active substrate 140) and further includes a top end portion 138 and a bottom end portion 139. The bottom end portion 139 is circumferentially connected to the bottom portion 121, such that the proximal sidewall 123 is connected to the top surface 128, and the distal sidewall 124 is connected to the bottom surface 127. The top end portion 138 is connected to the top surface 103 of the bulk substrate 101.

In some embodiments, the heavily doped layer 120 further includes a top horizontal extension 125 extended horizontally from the top end portion 138. The top horizontal extension 125 may be viewed as a top peripheral portion of the heavily doped layer 120. The peripheral heavily doped region 125 of the heavily doped layer 120 may also be viewed as a peripheral extension of the heavily doped layer 120 at the top surface 103 of the bulk substrate 101. For convenience, the top horizontal extension 125 is also referred to and used interchangeably as a "peripheral heavily doped region 125." The peripheral heavily doped region 125 extends vertically from a top surface 126 to a bottom surface 127. The top surface 126 is connected to the proximal sidewall 123 of the side portion 122 and coplanar with the top surface 103 of the bulk substrate 101. The bottom surface 129 is connected to the distal sidewall 124 of the side portion 122. In some embodiments, the peripheral heavily doped region 125 between two adjacent/neighboring SOI substrates (i.e., the SOI structures 102a and 102b), denoted as the peripheral heavily doped region 125b, may interconnect the heavily doped layers 120 of the two adjacent SOI substrates. In some embodiments, the heavily doped layer 120 encircles/surrounds and partially encloses the insulating layer 130 and the active substrate 140.

In some embodiments, the heavily doped layer 120 has substantially uniform doping concentration profile in the vertical direction. In alternative embodiments, the heavily doped layer 120 has a doping concentration gradient. For example, the doping concentration gradually decreases in the bottom portion 121 from the top surface 128 to the bottom surface 127. Similarly, the doping concentration gradually decreases from the proximal sidewall 123 to the distal sidewall 124 in the side portion 122. Similarly, the peripheral heavily doped region 125 may also have a doping concentration gradient. For example, the doping concentration may graduate decrease from the top surface 126 to the bottom surface 129 in the peripheral heavily doped region 125.

Like the heavily doped layer 120, the insulating layer 130 includes a bottom portion 131 and a side portion 132 circumferentially connected to the bottom portion 131. The bottom portion 131 is disposed on the bottom portion 121 of the heavily doped layer 120, and the side portion 132 is disposed on the side portion 122 (i.e., the proximal sidewall 123) of the side portion 122. The side portion 132 has a top surface 133 coplanar with the top surface 126 of the heavily doped layer 120 and the top surface 103 of the bulk substrate 101. The insulating layer 130 may be composed of an oxide or nitride such as silicon oxide (also referred to as buried oxide, or BOX), silicon nitride, silicon oxynitride, high-k dielectrics such as hafnium oxide (HfO₂), zirconium oxide (ZrO₂), or tantalum oxide (Ta₂O₅), or a combination thereof.

In some embodiments, the insulating layer 130 is composed of a thermal silicon oxide. Thermal silicon oxide is typically formed by exposing silicon to high temperatures in an oxygen-rich environment. As mentioned above, traditional SOI substrate usually has an insulating layer composed of a CVD silicon oxide. Compared with the CVD silicon oxide of the traditional SOI substrates, the thermal silicon oxide of the present insulating layer has better electrical properties and a higher-quality interface, a lower interface trap density, minimal charge trapping, higher uniformity, higher compatibility with other components, and thus is more cost effective and manufacture-feasible.

The active substrate 140 is disposed on and encircled/surrounded by the insulating layer 130. The active substrate 140 extends vertically from a top surface 143 to a bottom surface 141 and has a sidewall 142 circumferentially connected to the top surface 143 and the bottom surface 141. The top surface 143 is coplanar with the top surface 133 of the insulating layer 130, the top surface 126 of the heavily doped layer 120, and the top surface 103 of the bulk substrate 101. Similar to the bulk substrate, the active substrate 140 may be a semiconductor substrate such as silicon or a doped semiconductor substrate.

In the illustrated example, the active substrate 140 has an angle (α) formed between the sidewall 142 and the bottom surface 141, the insulating layer 130 has an angle (β) formed between the side portion 132 and the bottom portion 131, and the heavily doped layer 120 has an angle (γ) formed between the side portion 122 and the bottom portion 121 (or between the proximal sidewall 123 and the top surface 128 or between the distal sidewall 124 and the bottom surface 127). In some embodiments, the angles α, β, and γ are the same or substantially the same. In some embodiments, each of the angles α, β, and γ may be at least 85 degrees, at least 90 degrees, at least 100 degrees, at least 110 degrees, or at least 120 degrees. It should be noted that the other possible values of the angles α, β, and γ are also within the scope of the present disclosure.

The heavily doped layer 120 may have a thickness (T₁), measured by the vertical distance between the top surface 128 and the bottom surface 127 of the bottom portion 121, or a distance between the proximal sidewall 123 to the distal sidewall 124 of the side portion 122. The peripheral heavily doped region 125 similarly has a thickness (T₁) measured by a vertical distance between the top surface 126 and the bottom surface 129. The insulating layer 130 has a thickness (T₂) measured between the bottom surface 141 of the active substrate 140 and the top surface 128 of the heavily doped layer 120. The active substrate 140 has a thickness (T₃) measured between the top surface 143 and the bottom surface 141. The SOI structure 102 has a total thickness (T₄) measured as the total of T₁, T₂, and T₃. In some embodiments, T₁ is from 0.01 µm to 3 µm, from 0.05 µm to 2 µm, or from 0.1 µm to 1 µm. In some embodiments, T₂ is from 0.01 µm to 3 µm, from 0.05 µm to 2 µm, or from 0.1 µm to 1 µm. In some embodiments, T₃ is from 0.5 µm to 400 µm, from 1 µm to 200 µm, from 1 µm to 100 µm, or from 1 µm to 50 µm. In some embodiments, T₄ is from 0.5 µm to 400 µm, from 1 µm to 200 µm, from 1 µm to 100 µm, or from 1 µm to 50 µm. It should be noted that the other possible values of each of T₁, T₂, T₃, and T₄ are also within the scope of the present disclosure.

The IC device 145 formed in the active substrate 140 of the SOI structure 102 may be any type of passive and active semiconductor devices such as transistors, diodes, capacitors, resistors. Non-limiting examples of transistors include bipolar junction transistors (BJTs), field-effect transistors (FETs) such as metal-oxide-semiconductor field-effect transistors (MOSFETs), and junction field-effect transistors (JFETs). For example, the IC device 145 formed in the SOI substrate 102a may include a first transistor 145a and a second transistor 145b. Each of the transistors 145a and 145b may include two S/D regions 146 and a gate structure 147. The first and second transistors 145a and 145b may be separated and isolated by an STI structure 108 formed in the active substrate 140. A transistor 145c is formed in the active substrate 140 of the SOI structure 102b.

The MLI structure 115 is disposed on the top surface 103 of the bulk substrate 101, the top surface 143 of the active substrate 140, the top surface 133 of the insulating layer 130, and the top surface 126 of the heavily doped layer 120. The MLI structure 115 generally provides electrical routing and wiring for the IC device 145 included in the SOI structures 102. For example, the MLI structure 115 may be used to electrically connect the IC device 145 (e.g., the gate structure 147 of the transistor 145a or the S/D region 146 of the transistor 145c) to another component internal or external to the semiconductor structure 100.

The MLI structure 115 is a set of metallization layers (sometimes also referred to as "metal layers" or "M layer") that are added on one side of a substrate. The metallization layers are patterned to form a complex network of interconnects that connect the different components together. Each metallization layer is formed in a corresponding dielectric layer and includes multiple horizontal metal features (i.e., metal lines) and vertical metal features (i.e., via contacts) formed in the corresponding dielectric layer. In the illustrated example, the MLI structure 115 includes a base metallization layer (M0 layer), an M1 layer, an M2 layer, and an M3 layer. Additional M layers (e.g., M4 layer, M5 layer, etc.) may be formed sequentially on the top of the M3 layer. The M0 layer is formed on the top surface 103 of the bulk substrate 101 and includes a dielectric layer 111. The gate structure 147 of the transistors 145a, 145b, and 145c, as well as metal components of other IC devices may be formed in the dielectric layer 111. The M1, M2, and M3 layers respectively include dielectric layers 112, 113, and 114, and various metal lines and via contacts may be formed in each of the M1, M2, and M3 layers to form desired electrical routings.

The discharging metal structures 160 (e.g., 160a, 160b, and 160c) may be formed in the M1 layer and M0 layer of the MLI structure 115. In some embodiments, the discharging metal structure 160 includes a horizontal metal line 161 and multiple vertical via contacts 162. The metal line 161 extends horizontally in the M1 layer, and the via contact 162 extends vertically and is disposed in the M1 and/or M0 layer. One of the via contacts 162 electrically interconnects the IC device 145 (e.g., the gate structure 147 or the S/D region 146) and the metal line 161, and another one of the via contacts 162 electrically interconnects the peripheral heavily doped region 125. Accordingly, the discharging metal structure 160 provides an electrical path to allow release or dissipation of charges accumulated in the IC devices 145 and the active substrate 140 to the bulk substrate 101. Because the bulk substrate 101 can act as a ground plane, and the peripheral heavily doped region 125 of the heavily doped layer 120 further reduces the resistance, the electrical charges accumulated in the active substrate 140 can be effectively discharged through the electrical path provided by the discharging metal structures 160, without the need to form a through-insulator via that potentially damages the SOI structure 102. Additionally, the discharging metal structures 160 may be easily formed during the formation of the MLI structure 115 in the BEOL fabrication process without extra masks or additional processes, and thus is both manufacture-feasible and cost-effective.

In the illustrated example, multiple discharging metal structures 160 are formed. The discharging metal structure 160a interconnects the first transistor 145a to the peripheral heavily doped region 125a surrounding the SOI structure 102a. The discharging metal structure 160b interconnects the transistor 145b to the peripheral heavily doped region 125b, which is between the SOI structures 102a and 102b. The discharging metal structure 160c interconnects the third transistor 145c to the peripheral heavily doped region 125c, which is between the SOI structure 102b and the device region 150. It should be understood that additional discharging metal structures 160 may be formed, and the total number of the discharging metal structures 160 may depend on the number of IC devices in each SOI structure 102 and other design factors.

At least because of the partially enclosed and discrete characteristic of the present SOI structure 102, the SOI structure 102 may be formed in selected regions on the bulk substrate 101 (i.e., not the entire region of the bulk substrate). For example, the SOI structures 102 may be formed in selected regions wherein high priority IC devices are included (e.g., the regions of the bulk substrate 101 corresponding to the SOI structure 102a, 120b, and 102c shown in FIG. 1A), and other IC devices may be formed outside the SOI structure (e.g., the device regions 150 shown in FIG. 1A). The discharging metal structures 160 may be used to protect these high priority IC devices from antenna effect. Thus, the SOI structures according to the present disclosure provides more design flexibility as compared to the traditional SOI substrates with a planar insulating layer.

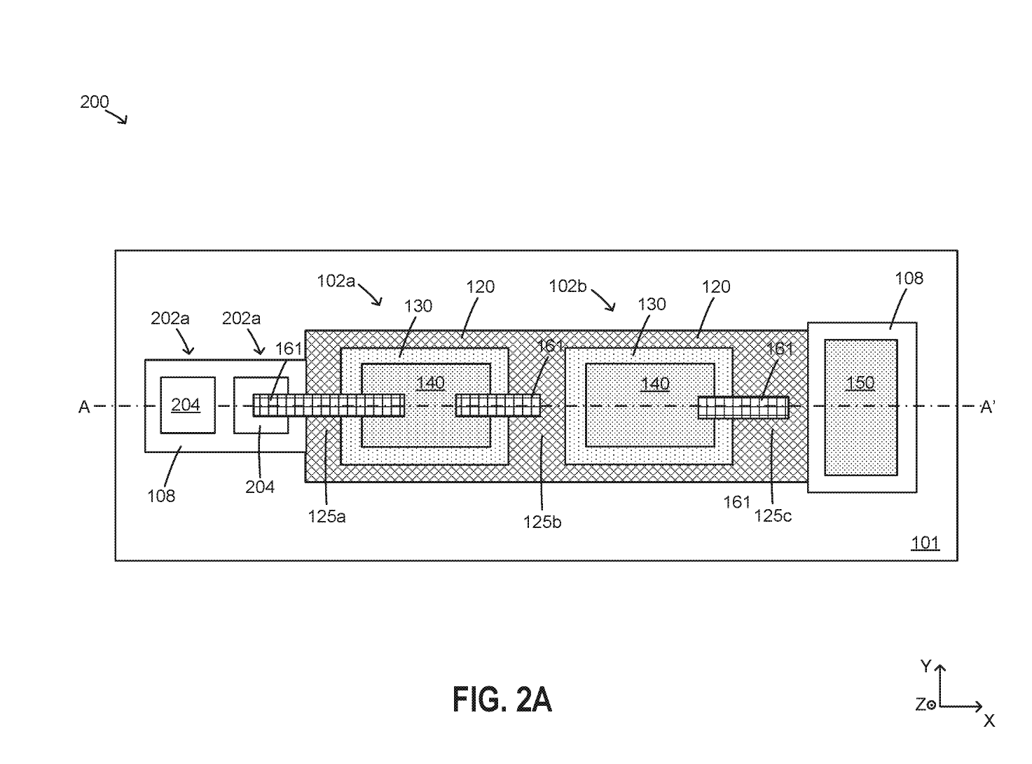

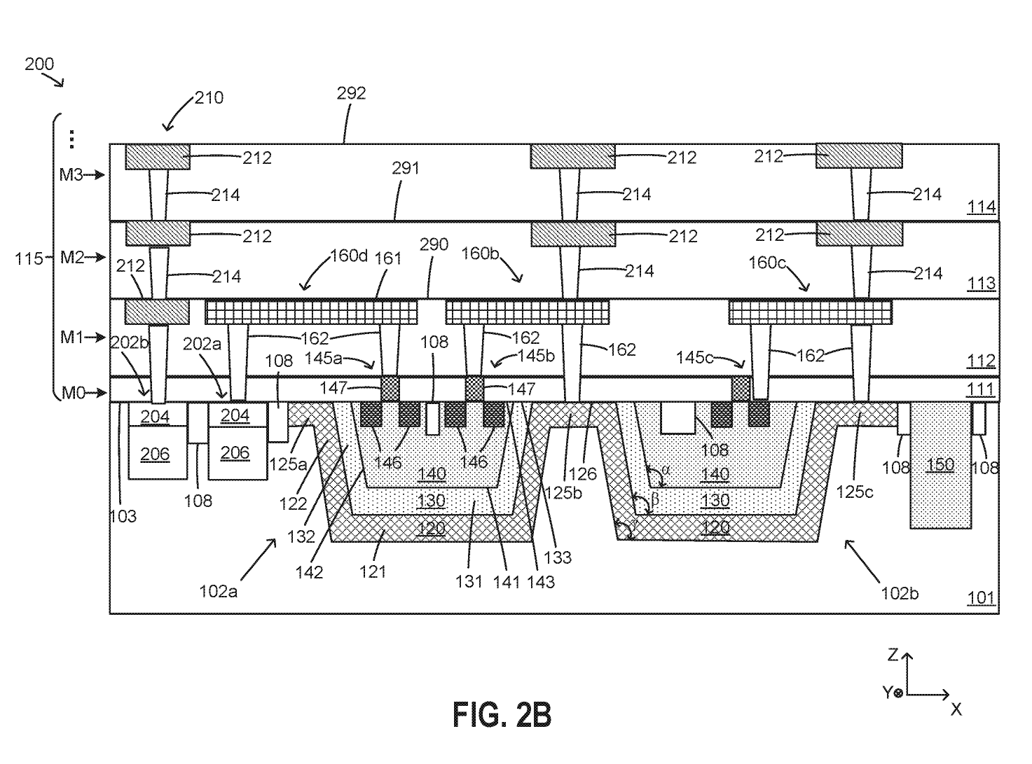

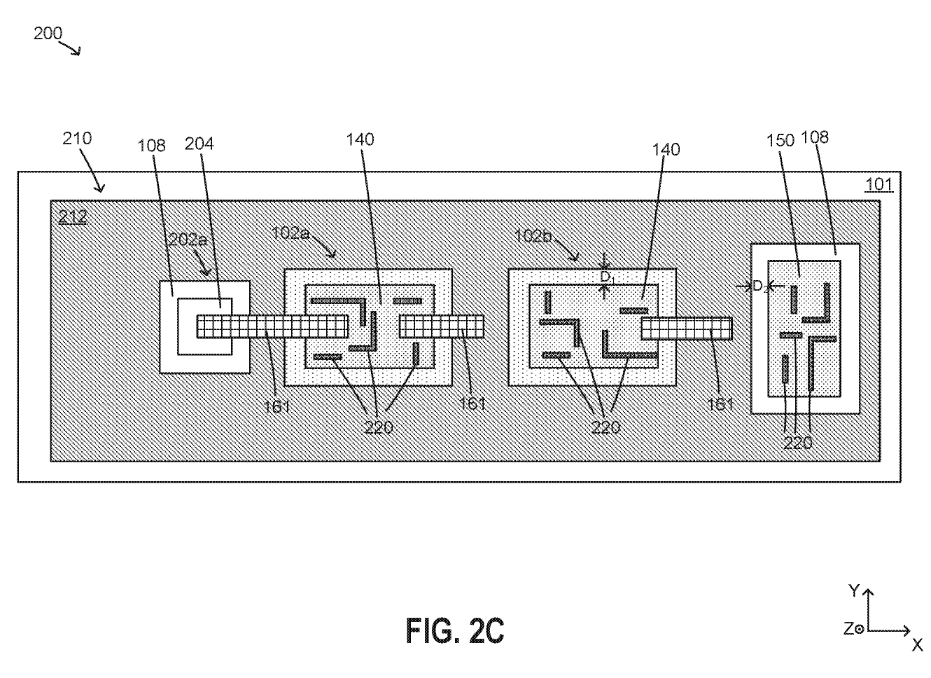

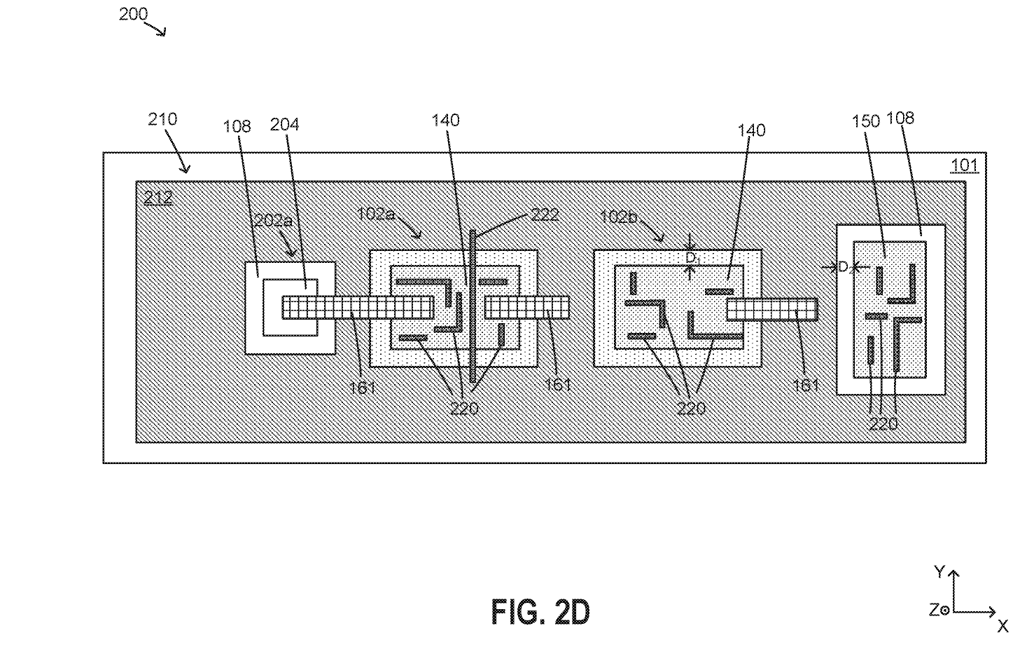

FIGS. 2A-2C illustrate another example semiconductor structure 200, in accordance with some embodiments. FIG. 2A is a schematic diagram illustrating a top view of a layout of the example semiconductor structure 200 from the surface 290 (i.e., the interface between M1 layer and M2 layer of the MLI structure 115). FIG. 2B is a schematic diagram illustrating a cross-sectional view of the example semiconductor structure 200 at an imaginary line A-A' of FIG. 2A. FIG. 2C is a schematic diagram illustrating a top view of a layout of the example semiconductor structure 200 from the surface 291 or 292 (i.e., the interface between M2 layer and M3 layer, or the top surface of M3 layer of the MLI structure 115)

For purposes of simplicity, some components such as the dielectric layers 114, 113, 112, and/or 111 are not illustrated in FIGS. 2A and 2C in order to depict other components of the semiconductor structure 200. The semiconductor structure 200 is a close variation of the semiconductor structure 100 and may include any components of the semiconductor structure 100. Various aspects of the similar components in the semiconductor structure 200 will not be repeated here unless otherwise indicated.

Similar to the semiconductor structure 100, the semiconductor structure 200 includes, among other components, a bulk substrate 101, multiple SOI structures 102a and 102b, multiple IC devices (e.g., transistors) 145a, 145b, and 145c, an MLI structure 115, and multiple discharging metal structures 160b, 160c, and 160d. Additional components, such as multiple device regions 150, multiple STI structures 108, etc., may also be included in the semiconductor structure 200. For example, the device region 150 is proximate to the SOI structure 102b and isolated from the SOI structure 102b by an STI structure 108. The peripheral heavily doped region 125c extends horizontally between the SOI structure 102b and the STI structure 180.

As shown in FIG. 2B, the semiconductor structure 200 further includes one or more antenna diodes 202. The antenna diode 202 is configured to reduce or prevent the antenna effect and further release or dissipate the unwanted charges accumulated in the IC devices 145 or other functional components in the SOI structures 102, device regions 150, and the MLI structures 115. It should be understood that the antenna diode is only one example of antenna effect protection device, and other type of devices or structures may also be used for the antenna effect protection device according to the present disclosure.

In some embodiments, the semiconductor structure 102 includes a first antenna diode 202a and a second antenna diode 202b (collectively as antenna diode 202) formed in the bulk substrate 101. The first antenna diode 202a is proximate to the SOI substrates 102a (i.e., proximate to the peripheral heavily doped region 125a of the heavily doped layer 120 of the SOI structure 102a). The second antenna diode 202b is located adjacent to the first antenna diode 202a and distal to the SOI structure 102a. The semiconductor structure 200 may include STI structures 108 used to isolate the first antenna diode 202a from the peripheral heavily doped region 125a and to isolate the first antenna diode 202a from the second antenna diode 202b. It should be understood that the number and location of the antenna diode 202 may vary depending on design requirements. For example, a pattern (e.g., a row, a column, or an array) of antenna diodes 202 may be formed in a region proximate to one of the SOI substrates 102. For another example, the antenna diodes 202 may be arranged in a periphery that surrounds or partially surrounds one of the SOI structures 102. The adjacent antenna diodes 202 (e.g., the first antenna diode 202a and the second antenna diode 202b) may be electrically connected.

Each of the antenna diodes 202 further includes a doping well 206 buried in the bulk substrate 101 and a heavily doped region 204 disposed on the doping well 204. In some embodiments, the doping well 206 and the heavily doped region 204 include a first dopant of a first semiconductor type (e.g., a p-type dopant or an n-type dopant), and the bulk substrate 101 includes a second dopant having a second semiconductor type. The second semiconductor type is opposite to the first semiconductor type. Thus, the bulk substrate 101, the heavily doped region 204, and the doping well 206 disposed therebetween form the antenna diode 202. In some embodiments, the bulk substrate 101 is a p-type substrate and includes a p-type dopant, while the doping well 206 and the heavily doped region 204 of the antenna diode 202 includes an n-type dopant. In some embodiments, the bulk substrate 101 is an n-type substrate and includes an n-type dopant, while the doping well 206 and the heavily doped region 204 of the antenna diode 202 includes a p-type dopant. In some embodiments, the heavily doped region 204 has a doping concentration higher or substantially higher than the doping concentration of the doping well 206 and the bulk substrate 101. In some embodiments, the doping well 206 has a doping concentration from 10¹³ to 10¹⁷ dopant atoms per square centimeter (cm²). In some embodiments, the heavily doped region 204 has a doping concentration from 10¹⁴ to 10²⁰ dopant atoms per square centimeter (cm²), or from 10¹⁵ to 10¹⁸ dopant atoms per square centimeter (cm²). It should be noted that the other possible values of the doping concentration of the heavily doped region 204 are also within the scope of the present disclosure. The antenna diode 202 is configured to have a low breakdown voltage so as to activate and conduct current when the voltage across the exceeds a certain threshold, thus providing a discharge path for the excess charge.

As shown in FIG. 2B, at least one of the discharging metal structures 160 (i.e., 160d) interconnects the first transistor 145a included in the SOI substrate 102a and the first antenna diode 202a. For example, one via contact 162 the discharging metal structures 160d interconnects the gate structure 147 of the transistor 145a to the metal line 161 of the first antenna diode 202a, and another via contact 162 the discharging metal structures 160d interconnects the heavily doped region 204 to the metal line 161 of the first antenna diode 202a. Accordingly, an electrical path is formed to electrically connect the active substrate 140 of the SOI substrate 102a to the bulk substrate 101, without use of a through-insulator via, and thus is more cost-effective and manufacture-friendly. The unwanted charges accumulated in the first transistor 145a can be discharged through the electrical path corresponding to the discharge metal structure 160d to the antenna diode 202a.

In some embodiments, the semiconductor structure 200 further includes an antenna metal structure 210 connected to at least one of the antenna diodes 202. The antenna metal structure 210 is an interconnect structure configured to electrically connect the antenna diode 202 to other components in of above the MLI structure 115. As shown in FIG. 2B, the antenna metal structure 210 may include one or more antenna metal layers 212 extending horizontally in one or more M layers (e.g., M1 layer, M2 layer, M3 layer, etc.) and multiple via contacts 214 interconnecting the antenna metal layers 212 in various M layers. The antenna metal layers 212 of the antenna metal structure 210 may be fabricated during the same process of forming the MLI structure 115. The antenna metal structure 210 provides additional electrical paths to release the unwanted charges accumulated in each of the M layers during the fabrication process and/or operation of the semiconductor structure 200. Further, the antenna metal structure 210 may be electrically connected to the discharging metal structure 160 (e.g., the discharging metal structures 160a, 160b, and 160c) to provide electrical paths for releasing charges in the M layers of the MLI structure 115 to the bulk substrate 101 through the antenna diode 202 and the peripheral heavily doped region 125.

As shown in FIG. 2C, the antenna metal layer 212 of the antenna metal structure 210 may be in a form of a continuous metal layer that overlays selected area of the bulk substrate 101. The antenna metal layer 212 may be disposed in M1 layer and formed during the same process as the metal line 161 of the discharging metal structure 160. As mentioned above, the antenna metal layer 212 may include multiple metal layers formed respectively in multiple M layers of the MLI structure 115 (e.g., M2 layer, M3 layer, etc.). The antenna metal layer 212 may not overlay the active substrate 140 of the SOI structures 102 in the vertical direction. Similarly, the antenna metal layer 212 may not overlay the device region 150. In some embodiments, the active substrate 140 may be spaced from the antenna metal layer 212 in the horizontal direction by a distance D₁. D₁ may be at least 0.2 µm, at least 0.5 µm, or at least 1 µm. In some embodiments, the device region 150 may be spaced from the antenna metal layer 212 in the horizontal direction by a distance D₂. D₂ may be at least 0.1 µm, at least 0.3 µm, or at least 0.5 µm. It should be noted that the other possible values of each of D₁ and D₂ are also within the scope of the present disclosure.

In some embodiments, the MLI structure 115 may include electrical routing structures 220 respectively used to interconnect the IC devices included in the active substrate 140 of the SOI structure 102a and 102b as well as the device region 150. The electrical routing structures 220 may include multiple horizontal metal lines and vertical vias in one or more M layers of the MLI structure 115. In some embodiments, the electrical routing structures 220 are not electrically connected to (i.e., are electrically isolated from) the antenna metal layer 212 of the antenna metal structure 210, particularly when the electrical potentials of the electrical routing structures 220 and the antenna metal layer 212 of the antenna metal structure 210 are different.

FIG. 2D is a schematic diagram illustrating a top view of a layout of another example semiconductor structure 200' in accordance with some embodiments. As shown in the example of FIG. 2D, the semiconductor structure 200' includes an interconnect metal 222 that interconnects the electrical routing structure 220 to the antenna metal layer 212 of the antenna metal structure 210. This arrangement may be useful when the electrical potentials of the electrical routing structure 220 and the antenna metal layer 212 of the antenna metal structure 210 are the same.

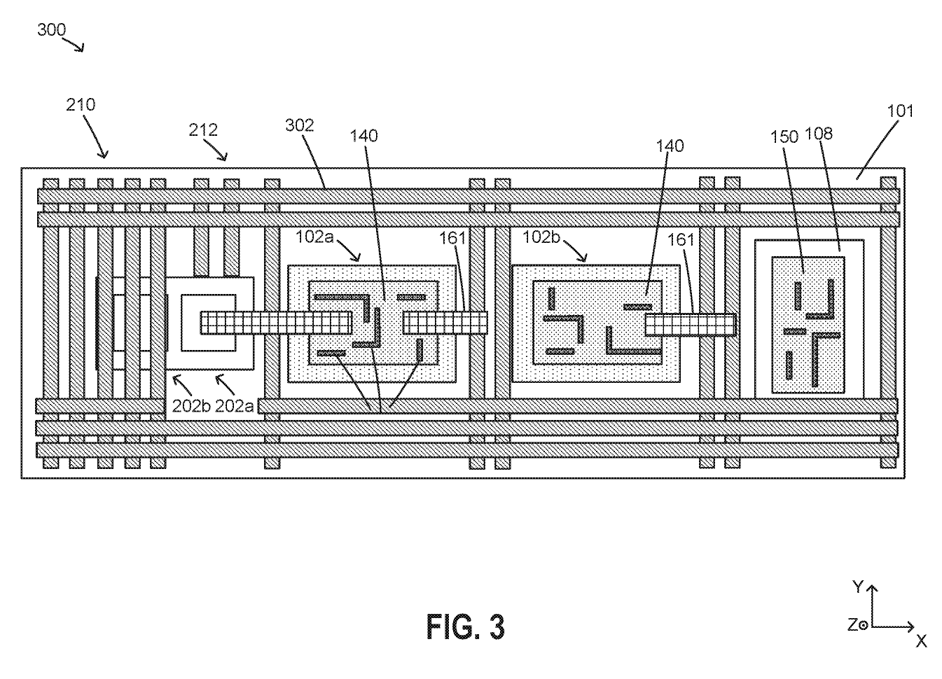

FIG. 3 is a schematic diagram illustrating a top view of a layout of another example semiconductor structure 300, which is a close variation of example semiconductor structure 200 of FIG. 2C. In the example of FIG. 3, the antenna metal layer 212 is in a form of multiple horizontally interconnected antenna metal lines instead of a single-piece and continuous metal layer. As illustrated, the antenna metal layer 212 includes multiple horizontally interconnected antenna metal lines 302 in one or more M layers of the MLI structure 115. The multiple horizontally interconnected antenna metal lines 302 may provide better routing flexibility, better current carrying capacity, and reduced material cost, as compared with the single-piece and continuous antenna metal layer.

### Example Fabrication Process Flow

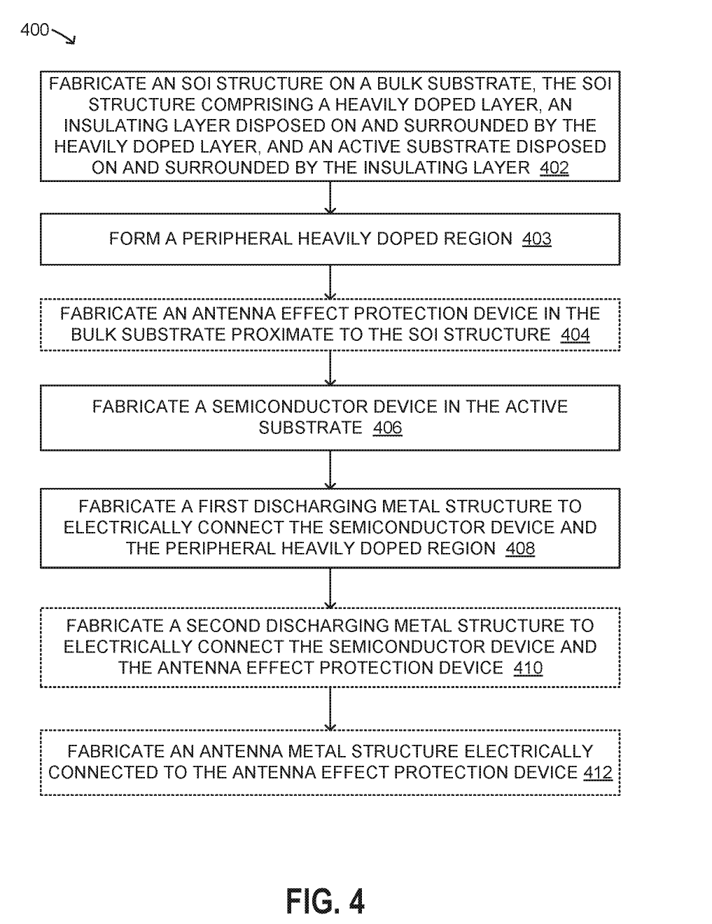

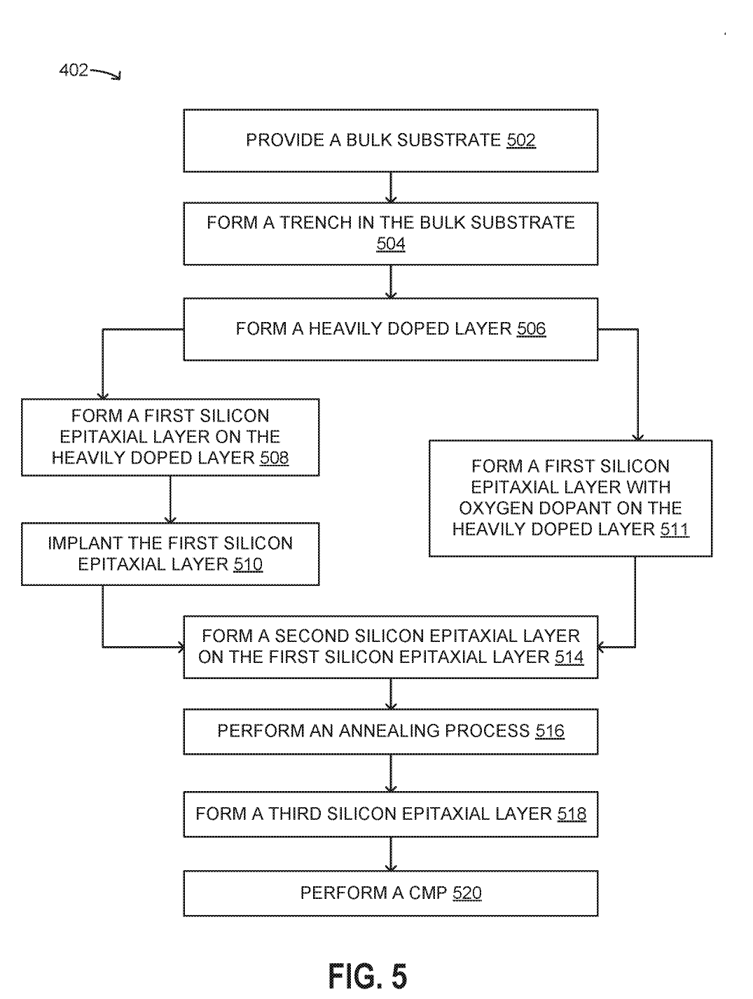

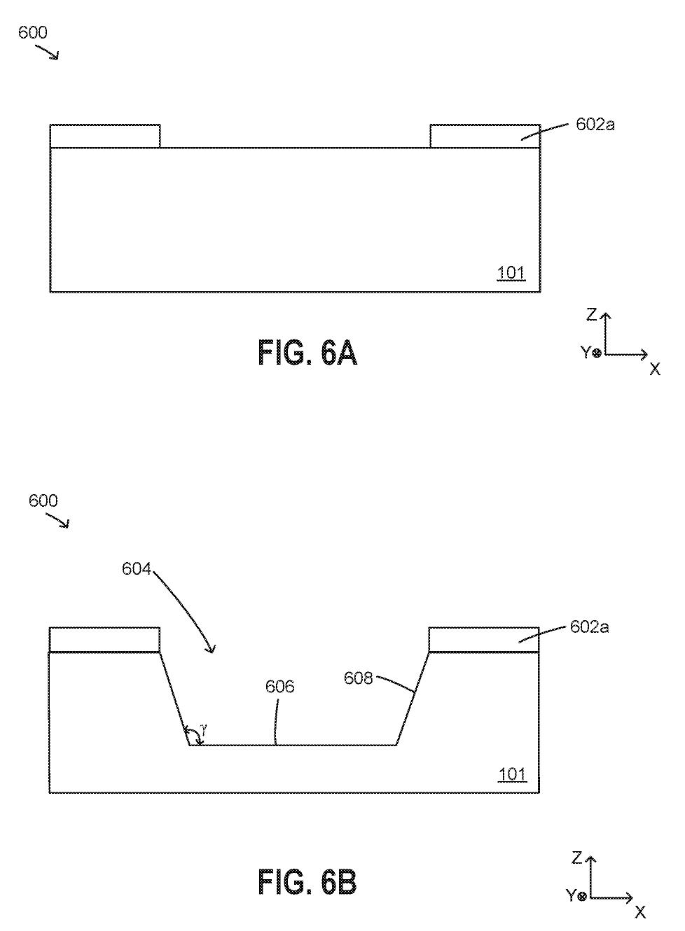

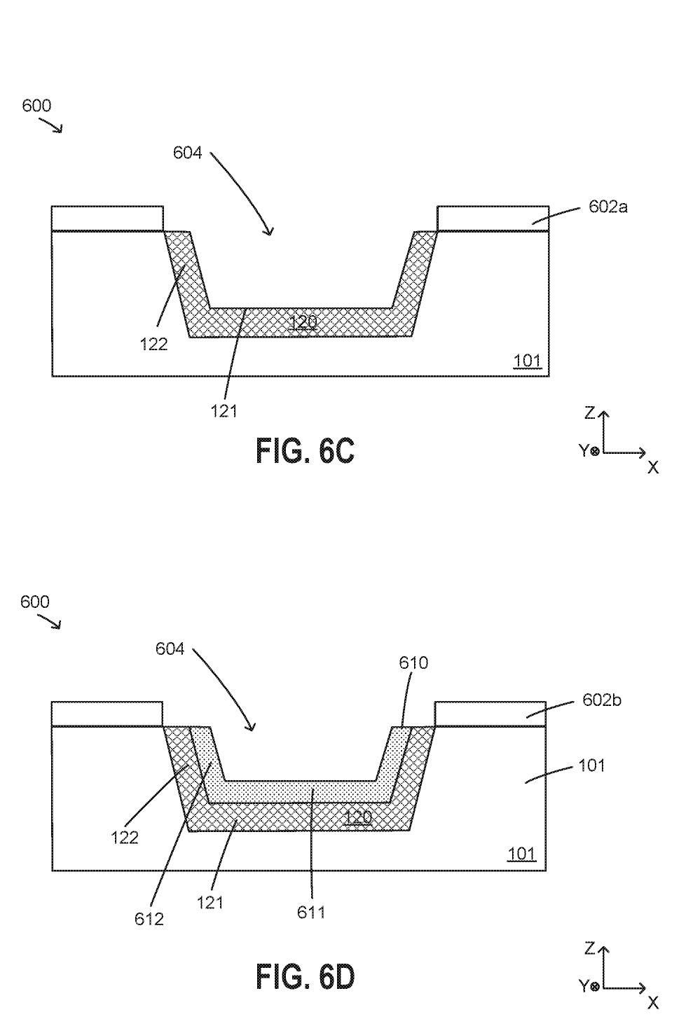

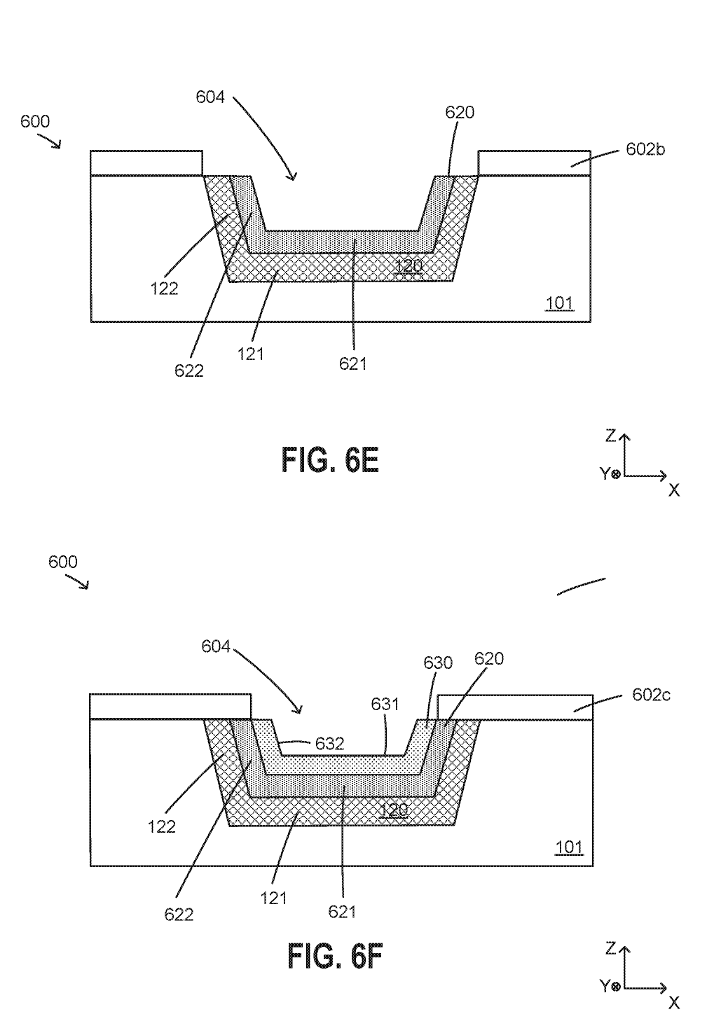

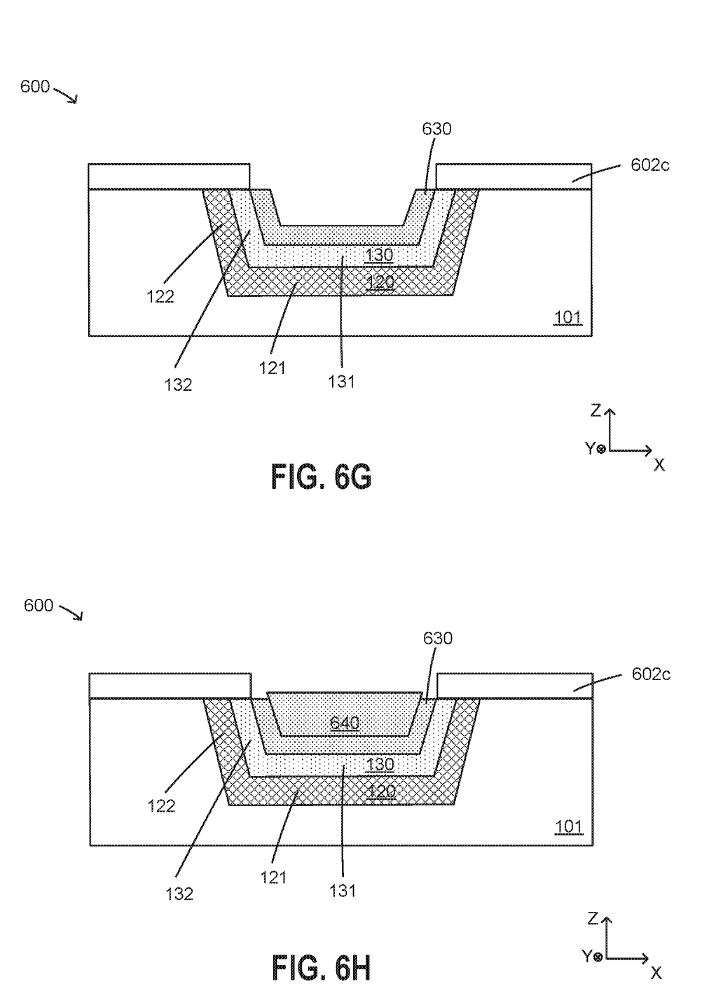

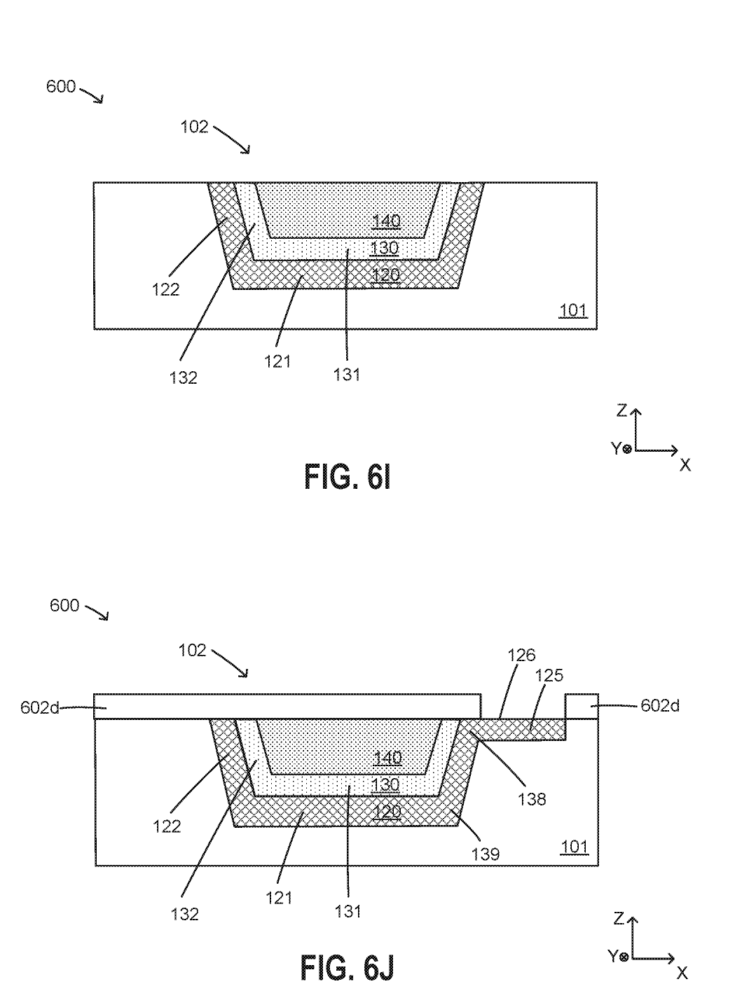

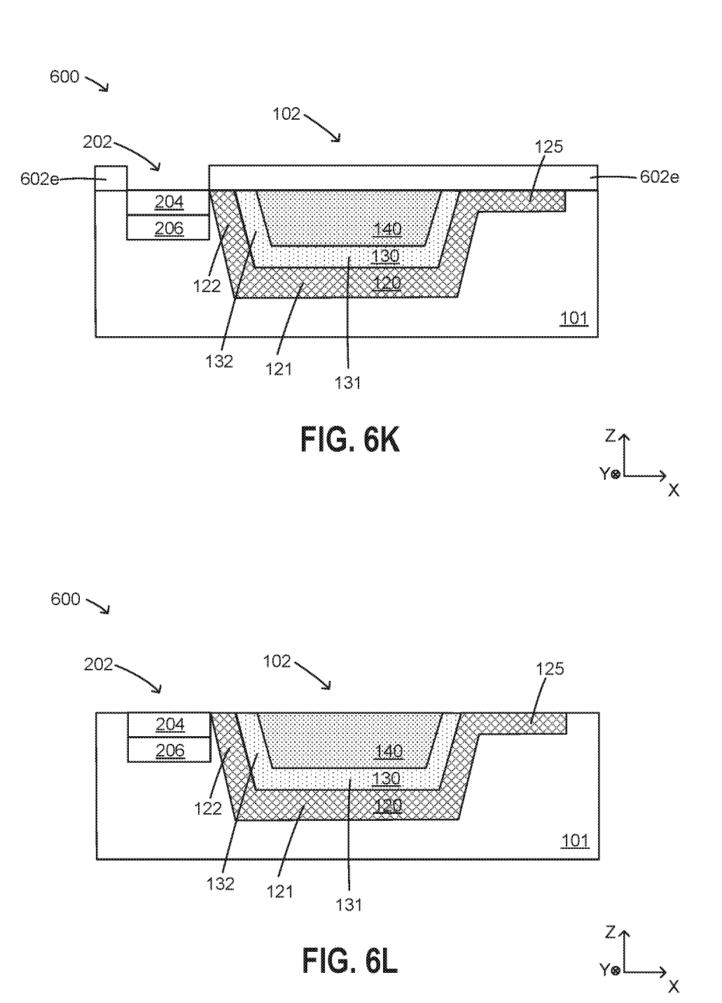

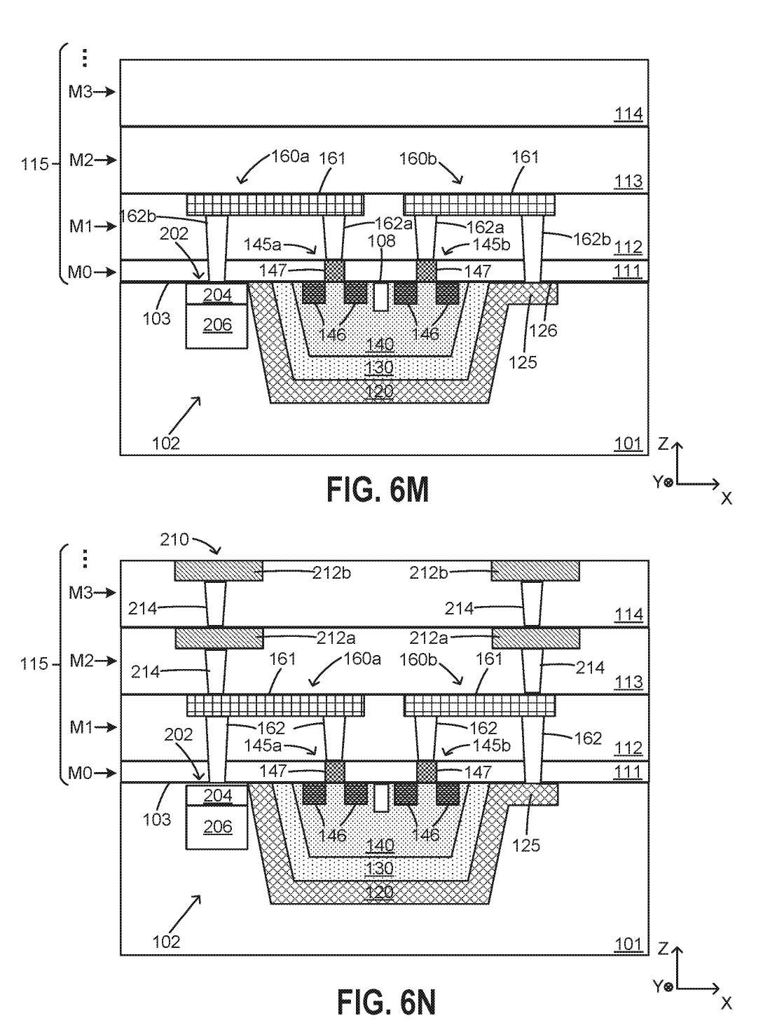

FIG. 4 is a flowchart diagram illustrating an example method 400 for fabricating a semiconductor structure 600 in accordance with some embodiments. FIG. 5 is a flowchart diagram illustrating an example operation 402 shown in FIG. 4 in accordance with some embodiments. FIGS. 6A-6N are cross-sectional diagrams illustrating the semiconductor structure 600, at various stages, fabricated using the example method 400 shown in FIG. 4 in accordance with some embodiments. It should be noted that the semiconductor structure 600 is a close variation of the semiconductor structures 100 and 200, and the semiconductor structures 100 and 200 may also be fabricated using method 400 or any operations thereof.

As shown in FIG. 4, the method 400 may include operations 402, 403, 406, and 408. In some embodiments, the method 400 may further include optional operations 404, 410, and 412. Additional operations may be performed. Additional operations may be performed. Also, it should be understood that the sequence of the various operations discussed with reference to FIGS. 4-5 is provided for illustrative purposes, and as such, other embodiments may utilize different sequences. These various sequences of operations are to be included within the scope of embodiments.

At 402, an SOI structure merged in on a bulk substrate is fabricated. The SOI structure includes a heavily doped layer, an insulating layer disposed on and surrounded by the heavily doped layer, and an active substrate disposed on and surrounded by the insulating layer. Examples of operation 402 are further described below with references to FIGS. 5 and 6A-6J.

Now referring to FIG. 5, operation 402 may include operations 502, 504, 506, 508 510, 514, 516, 518, and 520. In alternative embodiments, operation 402 may include operations 502, 504, 506, 511, 514, 516, 518, and 520.

At 502, a bulk substrate is provided. The bulk substrate may be a doped substrate such as a p-type substrate (e.g., p-doped silicon) or an n-type substrate (e.g., n-doped silicon).

At 504, a trench is formed in the bulk substrate. In some embodiments, the semiconductor substrate is selectively etched to form the trench. In some embodiments, the trench is etched by etching the area of the semiconductor substrate that is left exposed by the first mask pattern. In some embodiments, the first mask pattern is a photoresist mask pattern. In some embodiments, the first mask pattern is a hard mask pattern, and the hard mask pattern may include silicon oxide, silicon nitride, silicon oxynitride, or combinations thereof. In some embodiments, the bulk substrate is etched using wet etching. In some embodiments, the bulk substrate is etched using dry etching. In some embodiments, the bulk substrate is etched using plasma etching.

In the example shown in FIGS. 6A-6B, the bulk substrate 101 has an area that is left exposed by the first mask pattern 602a. The trench 604 is formed by etching the bulk substrate 101. After the bulk substrate 101 is etched, the trench 604 has a bottom 606 and a sidewall 608. The bottom 606 and the sidewall 608 define the angle (γ) shown in FIG. 1A. In some embodiments, the angle γ is larger than 85 degrees. In one example, the angle γ is 90 degrees. In another example, the angle γ is 100 degrees. In yet another example, the angle γ is 110 degrees. In still another example, the angle γ is 120 degrees. It should be noted that the other possible values of the angles α, β, and γ are also within the scope of the present disclosure.

At 506, a heavily doped layer is formed. In the example shown in FIG. 6C, the heavily doped layer 120 may be formed by performing an ion implantation process to implant a dopant into the bottom 606 and sidewall 608. Accordingly, a bottom portion 121 of the heavily doped layer 120 is formed on the bottom 606 and a side portion 122 of the heavily doped layer 120 is formed on the sidewall 608. In some embodiments, a p-type dopant such as boron, aluminum, gallium, or indium is implanted to form the heavily doped layer 120 (i.e., p+ layer). In some embodiments, an n-type dopant such as phosphorus, arsenic, or antimony is implanted to form the heavily doped layer 120 (i.e., n+ layer). In some embodiments, the dopant concentration of the heavily doped layer 120 is from 10¹⁴ to 10²⁰ dopant atoms per square centimeter (cm²) or 10¹⁵ to 10¹⁸ dopant atoms per square centimeter (cm²). It should be noted that the other possible values of the dopant concentration of the heavily doped layer 120 are also within the scope of the present disclosure. In some embodiments, the dopant concentration of the heavily doped layer 120 has a gradient distribution in the downward direction.

In some embodiments, operation 402 proceeds from operation 506 to operation 508. At 508, a first silicon epitaxial layer is formed on the heavily doped layer. The first silicon epitaxial layer may be epitaxially grown on the heavily doped layer. In some embodiments, the first silicon epitaxial layer is epitaxially grown using chemical vapor deposition (CVD) techniques (e.g., metal-organic chemical vapor deposition (MOCVD), atmospheric-pressure CVD (APCVD), low-pressure CVD (LPCVD), ultra-high-vacuum CVD (UHVCVD)), molecular beam epitaxy (MBE), atomic layer deposition (ALD), other suitable techniques, or combinations thereof.

In the example shown in FIG. 6D, the first silicon epitaxial layer 610 is formed on the heavily doped layer 120. A second mask pattern 602b covers the top surface of the side portion 122 of the heavily doped layer 120 and the top surface of the bulk substrate 101, preventing the first silicon epitaxial layer from forming thereon. The first silicon epitaxial layer 610 corresponds to the insulating layer 130 which is formed in the subsequent operations.

At 510, an oxygen implantation process is performed to implant the first silicon epitaxial layer with oxygen and form an oxygen-implanted layer. The area of the bulk substrate left exposed by the second mask pattern is implanted with oxygen. As a result, oxygen is implanted into the semiconductor substrate below the surface of the bottom and sidewalls of the heavily doped layer. Depending on the implant energy and duration, the thickness of the oxygen-implanted layer may be adjusted. The thickness of the oxygen-implanted layer is defined as a portion below the top surface with oxygen concentration above a predetermined amount. In one example, the oxygen concentration ranges from 5×10¹⁵ cm⁻² to 5×10¹⁸ cm⁻². It should be understood that other oxygen concentration values can be employed in other examples.

In alternative embodiments, the operation 402 proceeds from operation 506 to operation 511. At 511, the oxygen-implanted layer is formed in a single process by adding oxygen dopant during the formation of the first silicon epitaxial layer, such that the operations 508 and 510 are performed simultaneously or in one step.

In the example shown in FIG. 6E, the oxygen-implanted layer 620 is formed. The oxygen-implanted layer 620 includes a bottom portion 621 disposed on the bottom portion 121 of the heavily doped layer 120 and a side portion 622 disposed on the side portion 122 of the heavily doped layer 120.

After the oxygen-implanted layer 620 is formed, the operation proceeds to operation 514. At 514, a second silicon epitaxial layer is formed on the oxygen-implanted layer. The second silicon epitaxial layer may be formed in a similar manner as the first silicon epitaxial layer. In the example of FIG. 6F, the silicon epitaxial layer 630 is formed on the oxygen-implanted layer 620. A third mask pattern 602c covers the top surface of the oxygen-implant layer 620, the top surface of the side portion 122 of the heavily doped layer 120, and the top surface of the bulk substrate 101, preventing the second silicon epitaxial layer 630 from forming thereon. The second silicon epitaxial layer 630 has a bottom portion 631 disposed on the bottom portion 621 of the oxygen-implanted layer 620 and a side portion 632 disposed on the side portion 622 of the oxygen-implanted layer 620.

At 516, an annealing process is performed to form an insulating layer. In some embodiments, the annealing process is a thermal annealing process. In one example, the temperature of the thermal annealing process ranges from 900 °C to 1100 °C. After the annealing process, the oxygen in the oxygen-implanted layer reacts with the silicon in the oxygen-implanted layer to form silicon dioxide. As a result, the oxygen-implanted layer transforms into a silicon dioxide layer, which constitutes the insulating layer between the second silicon epitaxial layer and the heavily doped layer. In the example of FIG. 6G, the insulating layer 130 is formed from the oxygen-implanted layer 620 after the annealing process. The insulating layer 130 includes a bottom portion 131 corresponding to the bottom portion 621 of the oxygen-implanted layer 620 and a side portion 132 corresponding to the side portion 622 of the oxygen-implanted layer 620.

At 518, a third silicon epitaxial layer is formed. The third silicon epitaxial layer may be formed in a similar manner as the first and second silicon epitaxial layers. In the example of FIG. 6H, the third silicon epitaxial layer 640 is formed on the second silicon epitaxial layer 630 and fills the remaining portion of the opening 604. The third silicon epitaxial layer 640 may, as shown in FIG. 6H, exceed the top surface of the second silicon epitaxial layer 630 in the vertical direction. The top surface of both the third silicon epitaxial layer 640 and the second silicon epitaxial layer 630 can be planarized in a subsequent planarization process, as will be discussed below.

At 520, a planarization process is performed. In the example of FIG. 6I, a chemical-mechanical planarization (CMP) process is performed on the top surface of the bulk substrate 101. After operation 520, the portion of the third silicon epitaxial layer that is outside the trench 604 or above the top surface of the bulk substrate 101 is removed. The remaining bulk majority of the third silicon epitaxial layer 640 and the second silicon epitaxial layer 630 together form the active substrate 140. As a result, SOI structure 102 is formed and includes the heavily doped layer 120, the insulating layer 130, and the active substrate 140.

Now referring back to FIG. 4, at 403, a peripheral heavily doped region is formed. The peripheral heavily doped region may be formed in a similar manner as the heavily doped layer. In the example of FIG. 6J, a fourth mask pattern 602d is applied to cover the top surface of the bulk substrate 101 and the SOI structure 102 and expose an opening in the peripheral region of the SOI substrate 102. An ion implantation process is then performed to implant a dopant of the same semiconductor type as the heavily doped layer 120 into the bulk substrate 101 at the peripheral region exposed to the opening to form the peripheral heavily doped region 125 therein. It is noted that the peripheral heavily doped region 125 may only partially (i.e., not entirely) surround the SOI structure 102, as shown in FIG. 6J. The peripheral heavily doped region 125 is connected to the side portion 122 of the heavily doped layer 120 and has a top surface 126 coplanar with the top surfaces of the bulk substrate 101 and the active substrate 140.

At optional operation 404, an antenna effect protection device is formed in bulk substrate. In some embodiments, the antenna effect protection device includes one or more antenna diodes merged into the bulk substrate. The antenna diodes are arranged and positioned close to the SOI in the horizontal direction. In some embodiments, the antenna diodes are formed by sequentially forming a doping well in the bulk substrate and forming a heavily doped region on the doping well. In some embodiments, the bulk substrate includes a first dopant, and the doping well and the heavily doped region each include a second dopant. The first dopant and the second dopant have opposite semiconductor types. In some embodiments, the first dopant is a p-type dopant, and the second dopant is an n-type dopant. In some embodiments, the first dopant is an n-type dopant, and the first dopant is a p-type dopant. Thus, the heavily doped region, the doping well, and the underlying bulk substrate form the antenna diode.

In the example of FIG. 6K, a fifth mask pattern 602e is applied to cover the top surface of the bulk substrate 101, the SOI structure 102, and the top surface of the peripheral heavily doped region 125 to expose an opening adjacent to the SOI substrate 102. A trench (not shown) may be formed in the area of the bulk substrate 101 corresponding to the opening. Sequential ion implantation processes are then performed to respectively form a doping well 206 and a heavily doped region 204 over the doping well 206. In some embodiments, a single implantation process may be formed to form the heavily doped region 204 and the doping well 206 in one step by adjusting the implantation parameters such as energy and dopant concentration. In some embodiments, the doping concentration of the heavily doped region 204 is higher than the doping concentration of the doping well 206 by at least one order (i.e., 10 times). The heavily doped region 204, the doping well 206, and the underlying bulk substrate 101 form the antenna diode 202.

In the example of FIG. 6L, a CMP process may be performed to planarize the top surface of the antenna diode 202, such that the top surfaces of the antenna diode 202 and the active substrate 140 are coplanar.

At operation 406, one or more IC devices (i.e., semiconductor devices) are formed in the active substrate or the SOI structure. In some embodiments, one or more transistors (e.g., MOS transistors) may be formed in the active substrate. In the example of FIG. 6M, multiple IC devices 145 are formed in the active substrates 140 of the SOI structures 102.

At operation 408, a first discharging metal structure is formed to electrically connect the IC device in the active substrate to the peripheral heavily doped region. The first discharging metal structure may be formed in the same process for the formation of an MLI structure over the bulk substrate 101 during BEOL fabrication. In the example of FIG. 6M, the first discharging metal structure 160b is formed. As an example, an M0 layer and an M1 layer are sequentially formed over the bulk substrate 101. A horizontal metal line 161 and two via contacts 162a and 162b (collectively as 162) are formed in the M1 layer and/or the M0 layer. In some embodiments, the first discharging metal structure 160b may be formed simultaneously with other metal lines and via contacts in the M0 and M1 layers in a damascene or dual-damascene processes. The first via contact 162a electrically connects the transistor 145b in the active substrate 140 and the metal line 161, and the second via contact 162b electrically connects the peripheral heavily doped region 125 to the metal line 161, thereby forming a first electrical path for the charges generated in the IC devices of the active substrate to be released and discharged to the bulk substrate 101 (i.e., the ground plane) through the peripheral heavily doped region 125.

At optional operation 410, a second discharging metal structure is formed to electrically connect the IC device in the active substrate to the antenna effect protection device. The second discharging metal structure may be formed in a similar manner and in the same process as the first discharging metal structure or during the same process for the formation of the MLI structure. In the example of FIG. 6M, the second discharging metal structure 160a is formed. Similar to the first discharging metal structure 160b, the second discharging metal structure 160a is formed by forming a horizontal metal line 161 in the M1 layer and two via contacts 162a and 162b in the M1 and/or M0 layer. The first via contact 162a electrically connects the first transistor 145a in the active substrate 140 and the metal line 161, and the second via contact 162b electrically connects the heavily doped region 204 of the antenna diode 202 to the metal line 161, thereby forming a second electrical path for the charges generated in the IC devices of the active substrate to be released and discharged to the bulk substrate 101 (i.e., the ground plane) through the antenna diode 202.

At optional operation 412, an antenna metal structure is formed to electrically connect the antenna effect protection device. The antenna metal structure may be formed by forming one or more antenna metal layers and interconnect vias during the formation of the M layers of the MLI structure. In the example of FIG. 6N, the antenna metal structure 210 is formed. The antenna metal structure 210 may be formed by sequentially forming one or more antenna metal layers 212 (e.g., an antenna metal layer 212a in the M2 layer and an antenna metal layer 212b in the M3 layer) during the formation of the M2 and M3 layers of the MLI structure 115, respectively. Multiple via contacts 214 are also formed to interconnect the antenna metal layers 212a/212b and the metal line 161 of the first and second discharging metal structures 160a/160b, such that the antenna metal structure 210 is also electrically connected to the antenna diode 202 and the peripheral heavily doped region 125. In some embodiments, an antenna metal layer 212 may also be formed in the M1 layer and directly connected to another antenna diode 202 (not shown). In some embodiments, multiple antenna metal layers 212 may be formed in one or more M layers above the M0 layer of the MLI structure 115, and the multiple antenna metal layers 212 in different M layers may be interconnected by via contacts.

### SUMMARY

In accordance with some aspects of the disclosure, semiconductor structures are provided. In one example, a semiconductor structure includes a bulk substrate having a top surface and a silicon-on-insulator (SOI) substrate merged in the bulk substrate. The SOI substrate further includes a heavily doped layer, an insulating layer disposed on and surrounded by the heavily doped layer, and an active substrate disposed on and surrounded by the insulating layer. The heavily doped layer further includes a bottom portion extending horizontally and a side portion extending circumferentially from a top end portion to a bottom end portion in a downward direction. The top end portion is connected to the top surface of the bulk substrate, and the bottom end portion is connected to the bottom portion. The active substrate is physically isolated from the bulk substrate by the insulating layer and the heavily doped layer. The active substrate has a top surface coplanar with the top surface of the bulk substrate. The semiconductor structure further includes one or more semiconductor devices disposed in the active substrate, a peripheral heavily doped region connected to and extending horizontally from the top end portion of the side portion of the heavily doped layer, and a discharging metal structure electrically interconnecting the semiconductor devices to the peripheral heavily doped region.

In another example, a semiconductor structure includes a bulk substrate having a top surface and a silicon-on-insulator (SOI) substrate merged in the bulk substrate. The SOI substrate further includes a heavily doped layer, an insulating layer disposed on and surrounded by the heavily doped layer, and an active substrate disposed on and surrounded by the insulating layer. The heavily doped layer further includes a bottom portion extending horizontally and a side portion extending circumferentially from a top end portion to a bottom end portion in a downward direction. The top end portion is connected to the top surface of the bulk substrate, and the bottom end portion is connected to the bottom portion. The active substrate is isolated by the insulating layer and the heavily doped layer and has a top surface coplanar with the top surface of the bulk substrate. The semiconductor structure further includes one or more semiconductor devices disposed in the active substrate, one or more antenna diodes merged in the bulk substrate and proximate to the SOI substrate, and a first discharging metal structure electrically interconnecting the semiconductor devices to the antenna diode.

In accordance with some aspects of the disclosure, methods for fabricating semiconductor structures are provided. In one example, a method includes providing a bulk substrate having a top surface and forming a heavily doped layer. The heavily doped layer includes a bottom portion extending horizontally and a side portion extending circumferentially from a top end portion to a bottom end portion in a downward direction. The top end portion is connected to the top surface of the bulk substrate, and the bottom end portion is connected to the bottom portion. The method further includes forming an insulating layer on the heavily doped layer and forming an active substrate on the insulating layer. The active substrate is isolated by the insulating layer and the heavily doped layer and has a top surface coplanar with the top surface of the bulk substrate. The method further includes forming one or more antenna diodes in the bulk substrate and proximate to the active substrate, forming one or more semiconductor devices in the active substrate, and forming a first discharging metal structure electrically interconnecting the semiconductor devices to the antenna diode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor structure, the method comprising:
providing a bulk substrate comprising a top surface;
forming a heavily doped layer, the heavily doped layer comprising:
a bottom portion extending horizontally; and
a side portion extending circumferentially from a top end portion to a bottom end portion in a downward direction, wherein the top end portion is connected to the top surface of the bulk substrate, and the bottom end portion is connected to the bottom portion;
forming an insulating layer on the heavily doped layer;
forming an active substrate on the insulating layer, wherein the active substrate is isolated by the insulating layer and the heavily doped layer and comprises a top surface coplanar with the top surface of the bulk substrate;
forming an antenna diode in the bulk substrate and proximate to the active substrate;
forming a semiconductor device in the active substrate; and
forming a first discharging metal structure electrically interconnecting the semiconductor device to the antenna diode.

2. The method of claim 1, wherein forming the antenna diode further comprises:
forming a doping well in the bulk substrate; and forming a heavily doped region on the doping well.

3. The method of claim 2, wherein the bulk substrate comprises a first dopant of a first semiconductor type, and the doping well and the heavily doped region comprise a second dopant of a second semiconductor type opposite to the first semiconductor type.

4. The method of claim 2, wherein the heavily doped region has a doping concentration higher than a doping concentration of the doping well by at least one order of magnitude.

5. The method of claim 1, further comprising:
performing a planarization process such that a top surface of the antenna diode and the top surface of the active substrate are coplanar.

6. The method of claim 1, further comprising:
forming a shallow trench isolation (STI) structure in the bulk substrate to isolate the antenna diode from the heavily doped layer.

7. The method of claim 1, further comprising:
forming an antenna metal structure electrically connected to the antenna diode, wherein the antenna metal structure comprises one or more antenna metal layers disposed in a multi-layer interconnect (MLI) structure.

8. The method of claim 1, wherein the bulk substrate is a p-type substrate and the antenna diode comprises an n-type dopant.

9. A method for fabricating a semiconductor structure comprising a silicon-on-insulator (SOI) structure, the method comprising:
providing a bulk substrate comprising a top surface;
forming a trench in the bulk substrate, the trench comprising a bottom and a sidewall;
forming a heavily doped layer on the bottom and the sidewall of the trench, the heavily doped layer comprising a bottom portion extending horizontally and a side portion extending circumferentially in a downward direction;
forming a first silicon epitaxial layer on the heavily doped layer;
performing an oxygen implantation process to implant oxygen into the first silicon epitaxial layer to form an oxygen-implanted layer;
forming a second silicon epitaxial layer on the oxygen-implanted layer;
performing an annealing process to transform the oxygen-implanted layer into an insulating layer comprising silicon dioxide; and
forming a third silicon epitaxial layer over the second silicon epitaxial layer to form an active substrate isolated from the bulk substrate by the insulating layer and the heavily doped layer.

10. The method of claim 9, wherein the annealing process is a thermal annealing process performed at a temperature ranging from 900 °C to 1100 °C.

11. The method of claim 9, wherein the oxygen implantation process implants oxygen at a concentration ranging from 5×10¹⁵ cm⁻² to 5×10¹⁸ cm⁻².

12. The method of claim 9, wherein forming the heavily doped layer comprises:
performing an ion implantation process to implant a dopant into the bottom and the sidewall of the trench.

13. The method of claim 9, wherein forming the trench comprises:
selectively etching the bulk substrate such that an angle formed between the bottom and the sidewall of the trench is at least 85 degrees.

14. The method of claim 9, further comprising:
performing a chemical-mechanical planarization (CMP) process to remove a portion of the third silicon epitaxial layer that is above the top surface of the bulk substrate, such that a top surface of the active substrate is coplanar with the top surface of the bulk substrate.

15. The method of claim 9, further comprising:
forming a semiconductor device in the active substrate;
forming an antenna diode in the bulk substrate proximate to the heavily doped layer; and
forming a discharging metal structure electrically interconnecting the semiconductor device to the antenna diode.

16. A method for fabricating a semiconductor structure, the method comprising:
providing a bulk substrate comprising a top surface;
forming a heavily doped layer, the heavily doped layer comprising:
a bottom portion extending horizontally; and
a side portion extending circumferentially from a top end portion to a bottom end portion in a downward direction, wherein the top end portion is connected to the top surface of the bulk substrate, and the bottom end portion is connected to the bottom portion;
forming an insulating layer on the heavily doped layer;
forming an active substrate on the insulating layer, wherein the active substrate is isolated by the insulating layer and the heavily doped layer;
forming a peripheral heavily doped region on the top surface of the bulk substrate, the peripheral heavily doped region connected to and extending horizontally from the top end portion of the side portion of the heavily doped layer;
forming a semiconductor device in the active substrate; and
forming a discharging metal structure electrically interconnecting the semiconductor device directly to the peripheral heavily doped region.

17. The method of claim 16, wherein forming the peripheral heavily doped region comprises:
applying a mask pattern to expose a peripheral region adjacent to the heavily doped layer; and
performing an ion implantation process to implant a dopant of the same semiconductor type as a dopant of the heavily doped layer.

18. The method of claim 16, wherein forming the discharging metal structure comprises:
forming a horizontal metal line in a metallization layer; and
forming a first via contact and a second via contact, wherein the first via contact connects the semiconductor device to the horizontal metal line, and the second via contact connects the peripheral heavily doped region to the horizontal metal line.

19. The method of claim 16, wherein the discharging metal structure is formed simultaneously with a base metallization (M0) layer and a first metallization (M1) layer of a multi-layer interconnect (MLI) structure using a damascene or dual-damascene process.

20. The method of claim 16, wherein the heavily doped layer and the peripheral heavily doped region are each formed to have a thickness from 0.1 µm to 1 µm.
